(19) United States
(12) Patent Application Publication
(10) Pub. No.: US 2008/0073108 A1
(43) Pub. Date: Mar. 27, 2008

(54) SURFACE MOUNTING TYPE ELECTRONIC COMPONENTS AND MANUFACTURING METHOD OF THE SAME

(75) Inventors: Kenji Saito, Gunma (JP); Kohzo Yogiashi, Gunma (JP)

Correspondence Address: KNOBBE MARTENS OLSON & BEAR LLP, 2040 MAIN STREET, FOURTEENTH FLOOR, IRVINE, CA, 92614, US

(73) Assignee: Taiyo Yuden Co., Ltd., Tokyo (JP)

(21) Appl. No.: 11/861,199

(22) Filed: Sep. 25, 2007

(30) Foreign Application Priority Data
Sep. 26, 2006 (JP) 2006-289225

(51) Int. Cl. H05K 1/03; B05D 5/12

(52) U.S. Cl. 174/256; 427/99.5

(57) ABSTRACT

One inventive aspect relates to a surface mounting type electronic component excellent in a mounting property and having desired equivalent series resistance (ESR). The component has an electronic component body, and at least a pair of terminal electrodes formed on a surface of the electronic component body. The terminal electrode has a conductive resin layer formed between a substrate metal layer and a metal plating layer. The first and second layers each comprise a curable resin and metal particles. The first layer is lower in the content of metal particles than the second layer.

### BACKGROUND OF THE INVENTION

1. Field of the Invention

The present invention relates to surface mounting type electronic components such as a multi-layer ceramic capacitor, a capacitor array, LCR composite components, etc., and a manufacturing method of the same, and relates to the structure of end termination electrode and the forming method of the same.

2. Description of the Related Technology

Surface mounting type electronic components including a multi-layer ceramic capacitor have an element assembly of electronic components comprising internal electrodes buried inside the element assembly having a substantially hexahedral form, and at least a pair of end termination electrodes electrically connecting to the internal electrodes. The end termination electrode is composed of besides a substrate metal layer connecting to the internal electrodes, a plurality of conductive layers such as a metal plating layer for protecting the substrate metal layer and for improving soldering wettability.

Multi-layer ceramic capacitors in recent years have been increased in the ratio of internal electrodes in the inside of layered body with the inclination of making to a lamella and increase in capacity, and at the same time equivalent series resistance (ESR) tends to lower. Multi-layer ceramic capacitors are characterized in that ESR is low, and they have been utilized in uses where such a characteristic is an advantage. However, when a circuit is formed with a large quantity of such low ESR multi-layer ceramic capacitors, the impedance of the circuit as a whole lowers beyond necessity. In particular, in circuits for use in high frequency domain, there is a problem that resonance occurs at certain frequency and use frequency domain narrows.

Therefore, as disclosed, e.g., in Japanese Patent 2578264, it is proposed to form a metal oxide film on the surface of an end termination electrode to make it function as resistance. This means makes it possible to heighten ESR by the metal oxide film and control the resistance by the metal oxide film. However, it is very difficult to control the oxidation of a terminal electrode with this means, so that an oxide film thickness cannot be controlled with ease and the control of resistance becomes difficult.

Accordingly, as disclosed in JP-A-5-283283 and JP-A-2001-223132 (the term “JP-A” as used herein means an “unexamined published Japanese patent application”), means to heighten resistance by inserting high resistance layers containing ruthenium oxide in series on an end termination electrode are proposed. With these means, the thickness control of high resistance layers is easy, and resistance can be easily controlled by the content of ruthenium oxide. However, it is known that ruthenium oxide is high in thermal fluctuation of resistance. Accordingly, it is necessary with these known arts to further bake conductive paste on high resistance layers, which introduces a problem that the fluctuation of resistance of ruthenium oxide becomes large by the heat at that time of baking. Therefore, these techniques are applicable to a circuit that does not necessitate strict control of resistance such as a snubber circuit but are unsuitable for a circuit that necessitates strict control of resistance such as a high frequency circuit and the like.

Therefore, there is proposed in JP-A-11-283866 a method of using a conductive resin containing a curable resin and metal particles as an end termination electrode and forming a high resistance layer by lowering the content of the metal particles in the conductive resin. According to this method, control of the thickness of the high resistance layer is easy and resistance can be regulated by the adjustment of the content of metal particles, so that resistance can be easily controlled. Further, since the hardening temperature of curable resins is not higher than 200° C., the method is advantageous in that thermal fluctuation of resistance is small. However, when trying to obtain high resistance, the conductivity of the surface of the high resistance layer lowers. Consequently, there arises a new problem that plating by electrolytic plating is difficult, and it is hard to form a plating layer for improving soldering wettability. As a result, a mounting property is decreased. Plating process is possible if it is plating by electroless plating, but a plating metal is formed even on the surface other than the surface of the end termination electrode, so that pretreatment such as masking and the like by a resist becomes necessary. However, such pretreatment is very difficult and costs a lot. To the contrary, when it is tried to improve a plating adhering property by electrolytic plating, resistivity of the conductive resin should be lowered, that is, conductivity has to be heightened, so that it is difficult to obtain a multi-layer ceramic capacitor having desired ESR.

### SUMMARY OF CERTAIN INVENTIVE ASPECTS

Certain inventive aspects reconcile the control of desired ESR and the improvement of a plating adhering property, thus obtaining surface mounting type electronic components excellent in a mounting property and having desired ESR.

A first inventive aspect relates to surface mounting type electronic components having an element assembly of electronic components comprising internal electrodes buried inside the element assembly of a substantially hexahedral form, and at least a pair of end termination electrodes formed on the surface where the internal electrodes of the element assembly of electronic components are bared and electrically connecting to the internal electrodes, wherein the end termination electrode has a substrate metal layer connecting to the internal electrode and adhering to the surface of the element assembly of electronic components, a conductive resin layer formed on the substrate metal layer and comprising a curable resin and metal particles, and at least one metal plating layer formed on the conductive resin layer, and the conductive resin layer is in layers of two or more resins different in the content of metal particles, and a first resin layer on the side of the substrate metal layer is lower in the content of metal particles than a second resin layer on which the metal plating layer is formed.

By making the content of metal particles in the first resin layer lower than the content in the second resin layer, resistivity can be heightened, and a plating adhering property can be bettered by making the content of the metal particles in the second resin layer higher than that in the first resin layer. Accordingly, desired ESR can be compatible with bettering of a plating adhering property, and surface mounting type electronic components having good soldering wettability, an excellent mounting property and desired ESR can be obtained.

A second inventive aspect relates to the surface mounting type electronic component, wherein, when the cross section of the surface mounting type electronic components is seen, taking the length of the first resin layer being in contact with the surface as a, and the length of the second resin layer being in contact with the surface as b on the surface on which the ends of end termination electrodes of the element assembly of electronic components are formed, a and b respectively satisfy a>0 and b≧0.

Since the substrate metal layer is completely covered with the highly resisting first resin layer, short pass by the exposure of the substrate metal layer can be restrained, and desired ESR can be obtained. Further, since the second resin layer almost covers the first resin layer, the plating adhering property of the conductive resin layer can be bettered.

Another inventive aspect relates to a method for manufacturing surface mounting type electronic components comprising preparing an element assembly of electronic components comprising a substrate metal layer formed on the surface where an internal electrode of an element assembly of a substantially hexahedral form is bared, forming a conductive resin layer comprising a curable resin and metal particles on the substrate metal layer, and forming a metal plating layer by electrolytic plating on the conductive resin layer, wherein the process of forming the conductive resin layer has a process of forming a first resin layer by coating a first resin on the substrate metal layer and curing, followed by coating a second resin higher in the content of metal particles than the first resin and curing to form a second resin layer.

According to the manufacturing method, a high resistance first resin layer can be formed so as to obtain desired ESR, and a second resin layer can be formed so as to obtain a sufficient plating adhering property.

According to the foregoing inventive aspects, surface mounting type electronic components excellent in a mounting property and having desired ESR can be obtained while reconciling controlling to desired ESR with bettering a plating adhering property.

### BRIEF DESCRIPTION OF THE DRAWINGS

FIG. 1 is an imitative sectional view showing the multi-layer ceramic capacitor according to one embodiment.

FIG. 2 is an enlarged view of the dotted part in FIG. 1.

### DETAILED DESCRIPTION OF CERTAIN INVENTIVE EMBODIMENTS

The embodiments of the surface mounting type electronic components according to the invention will be explained by taking a multi-layer ceramic capacitor as an example. These embodiments are applicable particularly to composite electronic components having capacitor parts such as a capacitor array, an LC filter and the like besides a multi-layer ceramic capacitor.

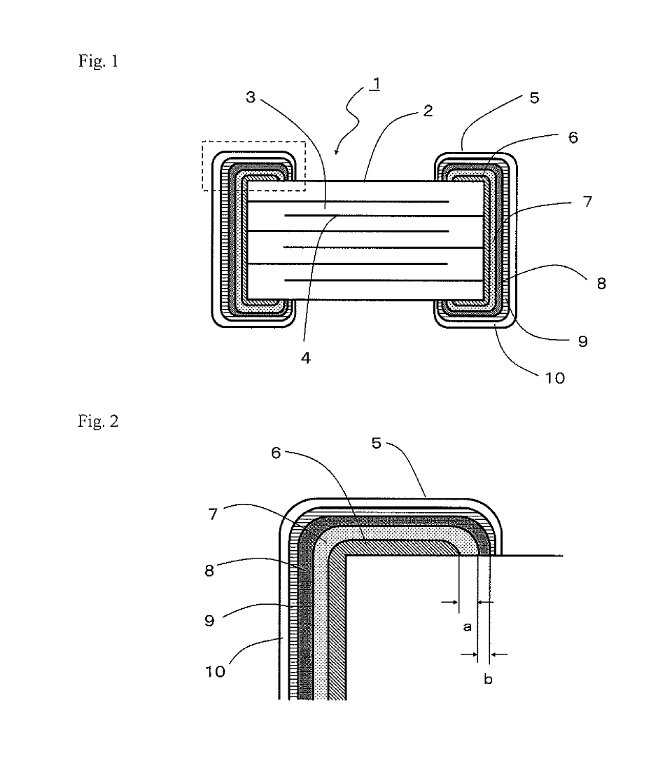

FIG. 1 is an imitative sectional view showing the multi-layer ceramic capacitor according to one embodiment. Multi-layer ceramic capacitor 1 has such a structure that a pair of end termination electrodes 5 are formed on element assembly of electronic components 2 comprising internal electrodes 4 alternately piled up via dielectric ceramics 3 mainly comprising barium titanate. End termination electrode 5 has substrate metal layer 6 adhering to element assembly of electronic components 2 and electrically connecting to internal electrodes 4, a conductive resin layer having first resin layer 7 formed on substrate metal layer 6 and second resin layer 8 formed on first resin layer 7, first metal plating layer 9 formed on second resin layer 8, and second metal plating layer 10 formed on first metal plating layer 9 for improving soldering wettability.

Multi-layer ceramic capacitor 1 having such a structure can be obtained, for example, as follows. In the first place, ceramic powder mainly comprising barium titanate having an anti-reducing property is kneaded with an organic binder to form a slurry, and the obtained slurry is formed to a sheet-form with a doctor blade and the like to thereby obtain a ceramic green sheet. Ni conductive paste is coated in a prescribed pattern on the ceramic green sheet by screen-printing to form an internal electrode pattern. The ceramic green sheet having formed thereon internal electrode pattern is punched in a prescribed form. A prescribed number of the punched ceramic green sheets are piled up so as to be capable of forming electrostatic capacity and subjected to thermo-compression bonding to obtain a layered body. The layered body is cut and split to a prescribed individual chip size (for example, a size of 4.0 mm×2.0 mm) to obtain an uncalcined body of element assembly of electronic components 2. Ni conductive paste containing the same material as above is coated by dipping on the internal electrode exposed face of the uncalcined body, calcined in the nitrogen-hydrogen atmosphere at approximately from 1,100 to 1,300° C. to prepare element assembly of electronic components 2 having a prescribed size (for example, a size of 3.2 mm×1.6 mm) having formed substrate metal layer 6. After calcining the uncalcined product, substrate metal layer 6 may be coated by dipping with conductive paste such as Cu and the like containing glass frit, and then baked in the nitrogen atmosphere at approximately from 700 to 800° C.

After that, a conductive resin layer having first resin layer 7 and second resin layer 8 is formed on substrate metal layer 6. The conductive resins for use in the conductive resin layer are the mixtures of metal particles such as Ag, Ni, Cu, Pd, Pt, Au, etc., and curable resins such as thermosetting resins or UV-setting resins, e.g., an epoxy resins, an acrylic resins, a melamine resins, a phenolic resins, a resol type phenolic resin, an unsaturated polyester resin, a fluorine resin, a silicone resin, etc. Further, a first resin for forming first resin layer 7 is lower in the content of metal particles than a second resin for forming second resin layer 8. The content of metal particles is expressed in the weight ratio of metal particles to a curable resin.

The conductive resin layer is formed as follows. In the first place, a first resin is coated on substrate metal layer 6 by a dipping method. The coated first resin is heated at about 150° C. for 10 minutes to be cured to form first resin layer 7. In the next place, a second resin is coated on first resin layer 7 by a dipping method. The coated second resin is heated at about 150° C. for 10 minutes to be cured to form second resin layer 8. A method of coating a second resin after coating a first resin while the first resin is uncured state, and curing both resins simultaneously is also considered, but when coating is performed in this manner, there is a possibility that the metal particles of the second resin flow toward the first resin, and the resistance of the first resin layer deviates from desired resistance. Accordingly, for achieving desired ESR, it is preferred to coat and cure a first resin, and then coat a second resin. Further, the thickness of a conductive resin layer and the contact length of the conductive resin layer with the element assembly of electronic components are adjusted by the viscosities of the resins and the depth of dipping of the element assembly of electronic components.

After that, a metal plating layer is formed by an electrolytic plating method on second resin layer 8. A metal plating layer may consist of one layer alone, but a plurality of metal plating layers of first metal plating layer 9 comprising Cu, Ni, and the like, for the purpose of protection of a substrate, and second metal plating layer 10 comprising Sn and the like with a view to improving soldering wettability may be formed.

The conductive resin layer will be described in detail below. FIG. 2 is an enlarged view of the dotted part in FIG. 1. The conductive resin layer comprises high resistance first resin layer 7 and low resistance second resin layer 8. Second resin layer 8 is a layer positioned at the outermost side of the layers on which a metal plating layer is formed, i.e., a conductive resin layer. First resin layer 7 is a layer positioned on the side of substrate metal layer 6, i.e., on the inner side of second resin layer 8. The conductive resin layer in the embodiment of the invention consists of two layers, but it may comprise three or more layers including other resin layers. In that case, other layer is formed between first resin layer 7 and second resin layer 8, or between first resin layer 7 and substrate metal layer 6, so as to attain desired ESR.

Since second resin layer 8 is required to have good plating adhering property, the content of metal particles is made high to let the resistance lower, so that electric current can flow easily in electrolytic plating. The relationship between the metal particle content of a conductive resin and a plating adhering property was evaluated here. In the first place, an element assembly of electronic components having formed a substrate metal layer was prepared. Moreover, conductive resins comprising Ag particles/epoxy resin in weight ratio of approximately from 80/20 to 30/70 were prepared. Each conductive resin was coated on the substrate metal layer and cured, and ten samples were manufactured per each sample. An Ni electrolytic metal plating layer was formed on each sample in a thickness of about 1 μm. In evaluation, a case where the Ni metal plating layer was formed on about 95% or more of the circumference of the conductive resin layer when seen from the cross section was graded o, and a case of less than 95% was graded x. The results of evaluation are shown in Table 1 below. The ratio of Ag particles/epoxy resin here is expressed by the weight ratio in a conductive resin before coating, but it may be found by the analysis of a conductive resin layer after coating and curing with EPMA (Electron Probe Micro-Analysis, X-ray micro-analyzer).

TABLE 1

| | Plating Adhering |
|---|---|
| Ag/Resin | Property |
| 80/20 | o |
| 70/30 | o |
| 60/40 | x |
| 50/50 | x |
| 40/60 | x |
| 30/70 | x |

From the above results, the samples containing Ag/resin until about 70/30 showed no problem in a plating adhering property. Therefore, from the viewpoint of a plating adhering property, metal particles/curable resin of second resin layer 8 is preferably from about 80/20 to 70/30.

Since first resin layer 7 is a constitutional requisite for increasing ESR of the surface mounting type electronic components of the embodiment, the content of metal particles is made low to let the resistance higher. The relationship between the metal particle content of a conductive resin and ESR was evaluated here. In the first place, an element assembly of electronic components having formed a substrate metal layer was prepared. Conductive resins of Ag particles/epoxy resin in weight ratio of from about 80/20 to 30/70 were also prepared. Each conductive resin was coated on the substrate metal layer and cured, and ten samples were manufactured per each sample. A conductive resin containing Ag particles/epoxy resin in weight ratio of about 80/20 was coated on the conductive resin layer of each sample and cured. An Ni electrolytic metal plating layer in a thickness of about 3 μm was further formed thereon. Model 4294A manufactured by Agirent Co. was used in the measurement of ESR, and the lowest value in the vicinity of resonance frequency was measured as ESR. The results of evaluation are shown in Table 2 below. The ratio of Ag particles/epoxy resin here is expressed by the weight ratio in a conductive resin before coating, but it may be found by the analysis of a conductive resin layer after coating and curing with EPMA (Electron Probe Micro-Analysis, X-ray micro-analyzer).

TABLE 2

| | ESR |
|---|---|
| Ag/Resin | (mΩ) |
| 80/20 | 10 |
| 70/30 | 25 |
| 60/40 | 153 |
| 50/50 | 450 |
| 40/60 | 1,160 |
| 30/70 | — |

From the above results, it has been found that ESR can be adjusted by the regulation of the content of metal particles. From the results of the above evaluation of plating adhering property, the samples containing the ratio of metal particles/curable resin of from about 80/20 to 70/30 can satisfy a plating adhering property with the first resin layer alone, so that it is preferred to regulate metal particles/curable resin between about 60/40 and 40/60 with respect to first resin layer 7. The sample containing metal particles/curable resin in the ratio of about 30/70 did not conduct in the evaluation, so that ESR could not be measured.

In connection with the structure of the conductive resin layer, when seen from the cross section, on the surface on which the ends of end termination electrodes of the element assembly of electronic components are formed, the length a of first resin layer 7 being in contact with the surface, and the length b of second resin layer 8 being in contact with the surface are preferably a>0 and b≧0, respectively.

It is preferred that first resin layer 7 is formed so as to cover substrate metal layer 6 and to be completely shut off from the outside. The reason for this is that when substrate metal layer 6 is exposed to the outside and directly brought into connection with the external circuit, the effect of first resin layer 7 of high ESR is lost. Accordingly, it is preferred for first resin layer 7 to be brought into contact with element assembly of electronic components 2. When the contact length a is a>0, first resin layer 7 is in contact with element assembly of electronic components 2, and substrate metal layer 6 is completely shut off from the outside. As the specific example of the contact length a, from about 10 to 100 μm is sufficient, and from about 10 to 50 μm is preferred.

Since second resin layer 8 is a layer to compensate for the low plating adhering property of first resin layer 7, it is sufficient for second resin layer 8 to cover the surface of first resin layer 7, and it is not especially necessary to be brought into contact with element assembly of electronic components 2. Accordingly, the contact length b of second resin layer 8 and element assembly of electronic components 2 of b≧0 will suffice.

The surface mounting type electronic components according to the foregoing embodiments have been described above, but, for example, an end termination electrode may be positioned anywhere on the surface of the element assembly of electronic components so long as it does not depart departing from the scope of the invention.

Further information on these embodiments may be found in Japanese Patent Application No. 289225/2006, filed on Sep. 26, 2006, which is hereby incorporated by reference in its entirety.

The foregoing description details certain embodiments of the invention. It will be appreciated, however, that no matter how detailed the foregoing appears in text, the invention may be practiced in many ways. It should be noted that the use of particular terminology when describing certain features or aspects of the invention should not be taken to imply that the terminology is being re-defined herein to be restricted to including any specific characteristics of the features or aspects of the invention with which that terminology is associated.

While the above detailed description has shown, described, and pointed out novel features of the invention as applied to various embodiments, it will be understood that various omissions, substitutions, and changes in the form and details of the device or process illustrated may be made by those skilled in the technology without departing from the spirit of the invention. The scope of the invention is indicated by the appended claims rather than by the foregoing description. All changes which come within the meaning and range of equivalency of the claims are to be embraced within their scope.

What is claimed is:

1. A surface mounting type electronic component having an element assembly of electronic components comprising internal electrodes buried inside the element assembly of a substantially hexahedral form, and at least a pair of end termination electrodes formed on the surface where the internal electrodes of the element assembly of electronic components are exposed and electrically connecting to the internal electrodes,
wherein each end termination electrode has a substrate metal layer connecting to the internal electrode and adhering to the surface of the element assembly of electronic components, a conductive resin layer formed on the substrate metal layer and comprising a curable resin and metal particles, and at least one metal plating layer formed on the conductive resin layer, and
the conductive resin layer is in layers of two or more resins different in the content of metal particles, and a first resin layer on the side of the substrate metal layer is lower in the content of metal particles than a second resin layer on which the metal plating layer is formed.

2. The surface mounting type electronic component of claim 1, wherein, when the cross section of the surface mounting type electronic component is seen, taking the length of the first resin layer being in contact with the surface as a, and the length of the second resin layer being in contact with the surface as b on the surface on which the ends of end termination electrodes of the element assembly of electronic component are formed, a and b respectively satisfy a>0 and b≧0.

3. A method of manufacturing a surface mounting type electronic component comprising
preparing an element assembly of an electronic component comprising a substrate metal layer connecting to an internal electrode of the element assembly,
forming a conductive resin layer comprising a curable resin and metal particles on the substrate metal layer, and
forming a metal plating layer on the conductive resin layer,
wherein the forming of the conductive resin layer comprises forming a first resin layer on the substrate metal layer, and forming a second resin layer higher in the content of metal particles than the first resin layer.

4. The method of claim 3, wherein the forming of a metal plating layer is by electrolytic plating.

5. The method of claim 3, wherein the forming of a resin layer is by coating and curing.

6. A surface-mounting electronic component having an electronic component body, and at least a pair of terminal electrodes formed on a surface of the electronic component body, at least one of the terminal electrodes comprising:
a conductive resin layer formed between a substrate metal layer and a metal plating layer, the substrate metal layer connecting to internal electrodes of the electronic component body, the conductive resin layer comprising at least a first resin layer adjoining the substrate metal layer and a second resin layer adjoining the metal plating layer, the first and second layers each comprising a curable resin and metal particles, wherein the first layer is lower in the content of metal particles than the second layer.

7. The electronic component of claim 6, wherein the electronic component comprises a multi-layer capacitor.

8. A terminal electrode suitable for being used in surface-mounting electronic component, the terminal electrode comprising:
a conductive resin layer formed between a substrate metal layer and a metal plating layer, the conductive resin layer comprising at least a first and second resin layer, the first and second layers each comprising a curable resin and metal particles, wherein the first layer is lower in the content of metal particles than the second layer.
